(19) United States
(12) Patent Application Publication
(10) Pub. No.: US 2013/0015516 A1
(43) Pub. Date: Jan. 17, 2013

(54) ASYMMETRICAL NON-VOLATILE MEMORY CELL AND METHOD FOR FABRICATING THE SAME

(71) Applicants: Sang Y. Kim, Kulim (MY); Sang H. Lee, Kulim (MY); Norhafizah Che May, Kulim (MY)

(72) Inventors: Sang Y. Kim, Kulim (MY); Sang H. Lee, Kulim (MY); Norhafizah Che May, Kulim (MY)

(21) Appl. No.: 13/545,178

(22) Filed: Jul. 10, 2012

(30) Foreign Application Priority Data
Jul. 11, 2011 (MY) PI 2011003254

(51) Int. Cl. H01L 29/788; H01L 21/336

(52) U.S. Cl. 257/316; 438/257; 257/E29.3; 257/E21.422

(57) ABSTRACT

The asymmetrical non-volatile memory cell is provided on a substrate of first conductivity type and comprises a control region and a floating region, wherein the control region is adjacent to the floating region and isolated from the floating region. The control region further comprises an implant region, having second conductivity type, disposed entirely across the control region and a polycrystalline silicon control gate disposed entirely over the implant region. The floating region further comprises a first voltage state of a drain implant region and a second voltage state of a source implant region, both having second conductivity type, the first voltage state is different from the second voltage state, a channel region that separates the drain implant region and the source implant region, and a polycrystalline silicon floating gate disposed entirely over the channel region and at least partially over the source implant region and drain implant region.

### FIELD OF INVENTION

The present invention relates generally to a non-volatile memory cell, more particularly a medium voltage non-volatile memory cell with asymmetrical floating gate architecture and method for fabricating the same.

### BACKGROUND ART

Non-volatile memory cells integrated within CMOS circuitry are being widely used in electronic equipment, such as multimedia devices, that require long-term storage and are required to be compact in size while maintaining an acceptable operation during programming, erasing and reading of the non-volatile memory cells.

Conventional non-volatile memory cells have a symmetrical architecture to ensure sufficient gate coupling ratio to maintain acceptable operation during programming, erasing and reading of the non-volatile memory cells. This however requires a wider transistor area and thereby increases the overall size of the non-volatile memory cell.

Several asymmetrical architectures of non-volatile memory cells have been introduced with the objective of reducing the overall size of the non-volatile memory cell while maintaining acceptable operation of the same, however, these architectures are either based on charge trapping layers or do not employ a control gate.

Therefore, it is preferable to have small to medium sized conventional non-volatile memory cells, with both a control and floating gate, to be integrated within CMOS circuitry, while maintaining an acceptable level of operation and these non-volatile memory cells to be fabricated using the standard CMOS process flow or with minimal modification of the same.

### SUMMARY OF INVENTION

The present invention relates generally to a non-volatile memory cell, more particularly a medium voltage non-volatile memory cell with asymmetrical floating gate architecture and method for fabricating the same. The present invention proposes the asymmetric floating gate architecture that would reduce the size of the medium voltage non-volatile memory cell by half while maintaining the floating gate coupling ratio to ensure acceptable programming, erasing or reading performance of the non-volatile memory cell. The present invention also proposes an efficient and cost-effective method for fabricating the asymmetric non-volatile memory cell by standardizing oxide thickness for both control and floating gate.

One aspect of the present invention is an asymmetrical non-volatile memory cell on a substrate of first conductivity type, the asymmetrical non-volatile memory cell comprising a control region and a floating region, wherein the control region is adjacent to the floating region and is isolated from the floating region. The control region further comprises an implant region, having second conductivity type, disposed entirely across the control region and a polycrystalline silicon control gate disposed entirely over the implant region. The floating region further comprises a first voltage state of a drain implant region, having second conductivity type and a second voltage state of a source implant region, having second conductivity type, the first voltage state is different from the second voltage state, a channel region that separates the drain implant region and the source implant region and a polycrystalline silicon floating gate disposed entirely over the channel region and at least partially over the source implant region and drain implant region.

In one embodiment of the present invention, the implant region, having second conductivity type, disposed across the entire control region further comprises a Buried N+ implant. The first voltage state of the drain implant region, having second conductivity type, further comprises a medium voltage between 3.3 Volts to 6.6 Volts, more preferably 6 Volts, lightly doped diffusion region, while the second voltage state of the source implant region, having second conductivity type, further comprises a low voltage between 1.35 Volts to 1.65 Volts, more preferably 1.5 Volts, lightly doped diffusion region.

In another embodiment of the present invention, the implant region, having second conductivity type, disposed across the entire control region further comprises a Buried N+ implant. The first voltage state of the drain implant region, having second conductivity type, further comprises a medium voltage between 3.3 Volts to 6.6 Volts, more preferably 6 Volts, lightly doped diffusion region, while the second voltage state of the source implant region, having second conductivity type, further comprises a zero voltage, lightly doped diffusion region.

In yet another embodiment of the present invention, the polycrystalline silicon control gate and the polycrystalline silicon floating gate have substantially equivalent gate oxide thickness and further comprise Nitride spacers. Additionally, the control region is isolated from the floating region by a trench.

Another aspect of the present invention is a method for fabricating an asymmetrical non-volatile memory cell on a substrate of first conductivity type. The method comprises firstly providing a control region adjacent to a floating region on the substrate, wherein the control region is isolated from the floating region. Thereafter, the fabrication method comprises performing an implantation process in the control region to form an implant region, having second conductivity type, across the control region. Following this, the method comprises forming a polycrystalline silicon control gate disposed entirely over the implant region of the control region and a polycrystalline silicon floating gate disposed entirely over a channel region and at least partially over a source implant region and a drain implant region of the floating region. Subsequently, the fabrication method comprises performing an implantation process in the floating region to form a first voltage state of the drain implant region, having second conductivity type and a second voltage state of the source implant region, having second conductivity type, the drain implant region and the source implant region separated by the channel region and the first voltage state is different from the second voltage state.

In one embodiment of the present invention, performing the implantation process in the control region to form the implant region, having second conductivity type, across the entire control region further comprises performing a Buried N+ implantation process. Performing the implantation process in the floating region to form the first voltage state of the drain implant region, having second conductivity type and the second voltage state of the source implant region, having second conductivity type, further comprises applying a mask over the source implant region, performing an implantation process to form a medium voltage between 3.3 Volts to 6.6 Volts, more preferably 6 Volts, lightly doped diffusion region of the drain implant region and performing an implantation process to form a low voltage between 1.35 Volts to 1.65 Volts, more preferably 1.5 Volts, lightly doped diffusion region of the source implant region.

In another embodiment of the present invention, performing the implantation process in the control region to form the implant region, having second conductivity type, across the entire control region further comprises performing a Buried N+ implantation process. Performing the implantation process in the floating region to form the first voltage state of the drain implant region, having second conductivity type and the second voltage state of the source implant region, having second conductivity type, further comprises applying a mask over the source implant region and performing an implantation process to form a medium voltage between 3.3 Volts to 6.6 Volts, more preferably 6 Volts, lightly doped diffusion region of the drain implant region.

In yet another embodiment of the present invention, forming the polycrystalline silicon control gate and the polycrystalline silicon floating gate further comprises forming the polycrystalline silicon control gate and the polycrystalline silicon floating gate with substantially equivalent gate oxide thickness and forming nitride spacers over the polycrystalline silicon control gate and the polycrystalline silicon floating gate. Additionally, the control region is isolated from the floating region by a trench.

### BRIEF DESCRIPTION OF THE ACCOMPANYING DRAWINGS

To further clarify various aspects of some embodiments of the present invention, a more particular description of the invention will be rendered by references to specific embodiments thereof, which are illustrated, in the appended drawings. It is appreciated that these drawings depict only typical embodiments of the invention and are therefore not to be considered limiting of its scope. The invention will be described and explained with additional specificity and detail through the accompanying drawings in which:

FIG. 1A is a vertical cross-section that illustrates one embodiment of the asymmetrical non-volatile memory cell, wherein the drain implant region comprises a medium voltage lightly doped diffusion region while the source implant region comprises a low voltage lightly doped diffusion region.

FIG. 1B is a vertical cross-section that illustrates another embodiment of the asymmetrical non-volatile memory cell, wherein the drain implant region comprises a medium voltage lightly doped diffusion region while the source implant region comprises a zero voltage lightly doped diffusion region.

FIG. 2 is a flow diagram depicting a standard CMOS flow utilized to produce the asymmetrical non-volatile memory cell of FIGS. 1A and 1B.

FIG. 3A is an illustration of a source-drain junction profile of a floating gate of the asymmetrical non-volatile memory cell based on a Technology Computer-Aided Design (TCAD) simulation.

FIG. 3B illustrates simulation results based on Technology Computer-Aided Design (TCAD) simulation of a floating gate of the asymmetrical non-volatile memory cell.

### DETAILED DESCRIPTION OF THE PREFERRED EMBODIMENTS

The present invention relates to a medium voltage non-volatile memory cell with asymmetrical floating gate architecture, method for fabricating and operating the same. Hereinafter, this specification will describe the present invention according to the preferred embodiments of the present invention. However, it is to be understood that limiting the description to the preferred embodiments of the invention is merely to facilitate discussion of the present invention and it is envisioned that those skilled in the art may devise various modifications and equivalents without departing from the scope of the appended claims.

The present invention relates particularly a medium voltage non-volatile memory cell with an asymmetrical floating gate architecture and method for fabricating the same. The asymmetric floating gate architecture reduces the size of the medium voltage non-volatile memory cell by half while maintaining the floating gate coupling ratio to ensure acceptable programming, erasing or reading performance of the non-volatile memory cell. The method for fabricating the asymmetric non-volatile memory cell is incorporated into the standard CMOS flow. Additionally, the method is efficient and cost-effective as oxide thickness for both control and floating gate of the medium voltage NMOS non-volatile memory cell are standardized.

The asymmetrical NMOS non-volatile memory cell is provided on a substrate of first conductivity type, which is a P-type. The asymmetrical architecture essentially lies in an asymmetric source-drain implant region introduced in a floating region of the non-volatile memory cell. The various embodiments of the present invention comprise two schemes of the asymmetric source-drain implant region.

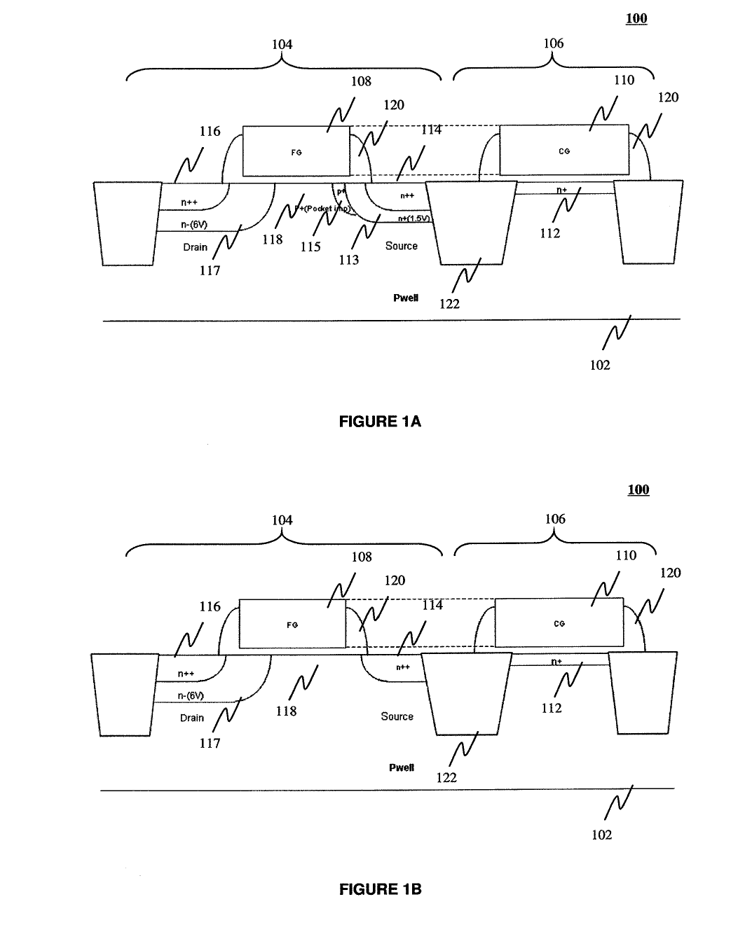

Reference is collectively being made to FIGS. 1A and 1B. FIG. 1A is a vertical cross-section that illustrates one embodiment of the asymmetrical non-volatile memory cell, wherein the drain implant region comprises a medium voltage lightly doped diffusion region while the source implant region comprises a low voltage lightly doped diffusion region. FIG. 1B is a vertical cross-section that illustrates another embodiment of the asymmetrical non-volatile memory cell, wherein the drain implant region comprises a medium voltage lightly doped diffusion region while the source implant region comprises a zero voltage lightly doped diffusion region.

The asymmetrical non-volatile memory cell (100) comprises a control region (106) and a floating region (104), wherein the control region (106) is adjacent to the floating region (104) and is isolated from the floating region (104). The control region (106) is isolated from the floating region (104) by means of trench (122) isolation, more specifically a Shallow Trench Isolation (STI).

According to the various embodiments of the present invention, the control region (106) further comprises an implant region (112) and a polycrystalline silicon control gate (110). The implant region (112) of the control region (106) is of second conductivity type, which is an N-type, and is disposed across the entire control region (106). More specifically, the implant region (112) comprises a Buried N+ (BN+) implant. The polycrystalline silicon control gate (110) is disposed entirely over the implant region (112).

According to the various embodiments of the present invention, the floating region (104) further comprises the drain implant region (116), the source implant region (114), a channel region (118) and a polycrystalline silicon floating gate (108). The drain implant region (116) and the source implant region (114) of the floating region (104) are also of second conductivity type, which is an N-type, and is disposed on either side of the floating region (104). The drain implant region (116) is of a first voltage state, which is a medium voltage state, while the source implant region (114) is of a second voltage state, which is either a low or zero voltage state. The channel region (118) separates the drain implant region (116) and the source implant region (114). The polycrystalline silicon floating gate (108) is disposed entirely over the channel region (118) and at least partially over the source implant region (114) and drain implant region (116).

The asymmetrical voltage state of the source-drain implant region contributes to the asymmetric floating region (104) architecture of the non-volatile memory cell (100). Due to the asymmetric floating region (104) architecture of the non-volatile memory cell (100), the length of the channel region (118) is reduced by almost half of the channel regions within conventional non-volatile memory cells. This in turn reduces the length of the floating region (104) or the floating gate transistor and thereby reducing the overall size of the non-volatile memory cell (100).

In one embodiment of the present invention, the asymmetrical voltage state of the source-drain implant region is contributed by a medium voltage (between 3.3V to 6.6V and more preferably 6V) lightly doped diffusion region (117) or MV NLDD in the drain implant region (116) and a low voltage (between 1.35V to 1.65V and more preferably 1.5V) lightly doped diffusion region (113) or LV NLDD in the source implant region (114).

In another embodiment of the present invention, the asymmetrical voltage state of the source-drain implant region is contributed by a medium voltage (between 3.3V to 6.6V and more preferably 6V) lightly doped diffusion region (117) or MV NLDD in the drain implant region (116) and a zero voltage (0V) lightly doped diffusion region (113) in the source implant region (114).

In yet another embodiment of the present invention, the polycrystalline silicon control gate (110) and the polycrystalline silicon floating gate (108) have substantially equivalent gate oxide thickness. The gate oxide thickness ranges between 100 Angstrom to 150 Angstrom. The gates comprise a medium voltage (between 3.3V to 6.6V and more preferably 6V) and have Nitride spacers (120).

The method for fabricating the asymmetric non-volatile memory cell according to the present invention begins with providing the asymmetrical NMOS non-volatile memory cell on a substrate of first conductivity type, which is a P-type.

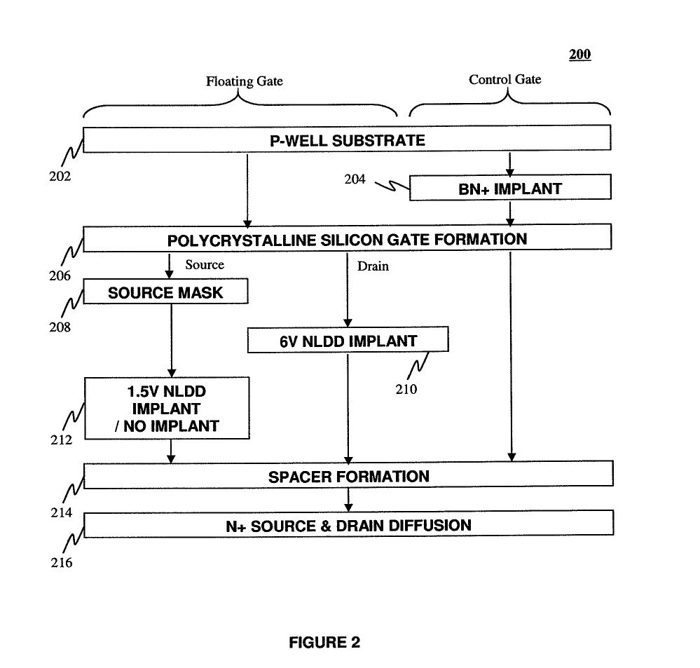

The method for fabricating the asymmetric non-volatile memory cell is incorporated into the standard CMOS flow. Reference is now made to FIG. 2. FIG. 2 is a flow diagram depicting a standard CMOS flow utilized to produce the asymmetrical non-volatile memory cell of FIGS. 1A and 1B, with the step of applying a mask over the source implant region (208) being the only addition to the standard CMOS flow utilized to fabricate conventional symmetrical non-volatile memory cell.

The method (200) for fabricating the asymmetrical non-volatile memory cell comprises providing a control region adjacent to a floating region on the substrate (202). The control region is isolated from the floating region by trench isolation, more specifically a Shallow Trench Isolation (STI).

Thereafter, an implantation process is performed in the control region (204) to form an implant region. This implant region is of a second conductivity type, which is an N-type, and formed such that it is disposed across the entire control region. More specifically, the implant region formed may be a Buried N+ implant.

Once the implant region of the control region is formed, polycrystalline silicon gates comprising a polycrystalline silicon control gate and a polycrystalline silicon floating gate are formed (206). The polycrystalline silicon control gate is formed such that it is disposed entirely over the implant region of the control region. The polycrystalline silicon floating gate is formed such that it is disposed entirely over a channel region and at least partially over a source implant region and a drain implant region of the floating region.

Subsequently an implantation process is performed in the floating region to form a first voltage state, which is a medium voltage state, of the drain implant region and a second voltage state, which is either a low or zero voltage state, of the source implant region, both having second conductivity type which is an N-type. The drain implant region and the source implant region are formed such that these regions are separated by the channel region in the floating region.

This specific implantation process produces an asymmetrical voltage state of the source-drain implant region that contributes to the asymmetric floating region architecture of the non-volatile memory cell. The various embodiments of the present invention comprise two methods of fabrication of the asymmetric source-drain implant region, where the difference in both methods lie in the step of performing or not performing an implantation process in the source implant region (212).

In one embodiment of the present invention, the fabrication of the asymmetrical voltage state of the source-drain implant region is performed by applying a mask over the source implant region (208), followed by two implantation processes, each on the drain implant region and the source implant region respectively. The implantation process performed on the drain implant region (210) forms a medium voltage (between 3.3V to 6.6V and more preferably 6V) lightly doped diffusion region or MV NLDD region, while the implantation process performed on the source implant region (212) forms a low voltage (between 1.35V to 1.65V and more preferably 1.5V) lightly doped diffusion region or LV NLDD region.

The mask applied over the source implant region (208) is a “Source_mrk” marking layer that is drawn over the source implant region (208) such that during implantation process performed on the drain implant region (210), the source implant region (208) will not receive the said implantation. Meanwhile, during implantation process performed on the source implant region (212), the source implant region (208) will be implanted while the drain implant region (116) will not be implanted. These implantations are based on the standard CMOS process flow.

In another embodiment of the present invention, the fabrication of the asymmetrical voltage state of the source-drain implant region is performed by applying a mask over the source implant region (208), followed by only one implantation process carried out on the drain implant region. The implantation process performed on the drain implant region (210) forms a medium voltage (between 3.3V to 6.6V and more preferably 6V) lightly doped diffusion region or MV NLDD region, while the absence of the implantation process on the source implant region (212) forms a zero voltage (0V) lightly doped diffusion region.

The mask applied over the source implant region (208) is a “Source mrk” marking layer that is drawn over the source implant region (208) such that during implantation process performed on the drain implant region (210), the source implant region (208) will not receive the said implantation. Meanwhile, during implantation process performed on the source implant region (212), the source implant region (208) will be implanted while the drain implant region (116) will not be implanted. These implantations are based on the standard CMOS process flow.

The method then comprises the formation of nitride spacers (214) over the polycrystalline silicon control gate and the polycrystalline silicon floating gate. Subsequently to complete the fabrication process, an NSD (N+ Source Drain) implantation process is carried out on the drain implant region and the source implant region of the floating region.

In yet another embodiment of the present invention, the polycrystalline silicon control gate and the polycrystalline silicon floating gate are formed (206) such that both gates have substantially equivalent gate oxide thickness and comprise a medium voltage (between 3.3V to 6.6V and more preferably 6V). The gate oxide thickness ranges between 100 Angstrom to 150 Angstrom.

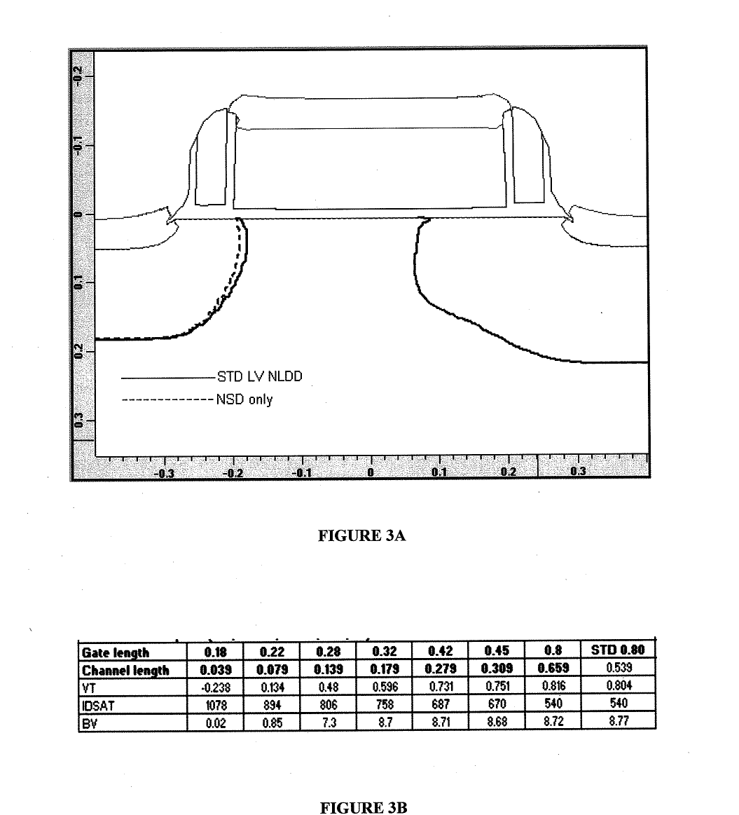

Reference is made collectively to FIGS. 3A and 3B. FIG. 3A is an illustration of a source-drain junction profile of the floating gate of the asymmetrical non-volatile memory cell based on a Technology Computer-Aided Design (TCAD) simulation. FIG. 3B illustrates simulation results based on Technology Computer-Aided Design (TCAD) simulation of the floating gate of the asymmetrical non-volatile memory cell. It can be observed from the results that the value of Breakdown Voltage (BV) is maintained at an acceptable level at approximately 8.7 V, the drain saturation current (ID SAT) is maintained below 800 μA/μm and the threshold voltage (VT) is maintained above 0.5 V although the size of the non-volatile memory cell has been reduced by 60%, i.e. from 0.8 μm to 0.32 μm. This ensures acceptable programming, erasing or reading performance of the non-volatile memory cell.

1. An asymmetrical non-volatile memory cell (100) on a substrate of first conductivity type, the asymmetrical non-volatile memory cell comprising
a control region (106); and
a floating region (104);
the control region (106) further comprising
an implant region (112), having second conductivity type, disposed entirely across the control region (106), wherein the second conductivity type is different from the first conductivity type; and
a polycrystalline silicon control gate (110) disposed entirely over the implant region (112);
the floating region (104) further comprising
a first voltage state of a drain implant region (116), having second conductivity type and a second voltage state of a source implant region (114), having second conductivity type, wherein the first voltage state is different from the second voltage state;
a channel region (118) that separates the drain implant region (116) and the source implant region (114); and
a polycrystalline silicon floating gate (108) disposed entirely over the channel region (118) and at least partially over the source implant region (114) and drain implant region (116);
wherein the control region (106) is adjacent to the floating region (104) and is isolated from the floating region (104).

2. An asymmetrical non-volatile memory cell (100) according to claim 1, wherein the implant region (112), having second conductivity type, disposed entirely across the control region (106) further comprises a Buried N+ implant.

3. An asymmetrical non-volatile memory cell (100) according to claim 1, wherein the first voltage state of the drain implant region (116), having second conductivity type, further comprises a medium voltage between 3.3 Volts to 6.6 Volts, more preferably 6 Volts, lightly doped diffusion region (117).

4. An asymmetrical non-volatile memory cell (100) according to claim 1, wherein the second voltage state of the source implant region (114), having second conductivity type, further comprises a low voltage between 1.35 Volts to 1.65 Volts, more preferably 1.5 Volts, lightly doped diffusion region (113).

5. An asymmetrical non-volatile memory cell (100) according to claim 1, wherein the second voltage state of the source implant region (114), having second conductivity type, further comprises a zero voltage lightly doped diffusion region (113).

6. An asymmetrical non-volatile memory cell according to claim 1, wherein the polycrystalline silicon control gate (110) and the polycrystalline silicon floating gate (108) have substantially equivalent gate oxide thickness.

7. An asymmetrical non-volatile memory cell according to claim 1, wherein the polycrystalline silicon control gate (110) and the polycrystalline silicon floating gate (108) further comprises Nitride spacers (120).

8. An asymmetrical non-volatile memory cell according to claim 1, wherein the asymmetrical non-volatile memory cell further comprises at least one trench (122) to isolate the control region (106) from the floating region (104).

9. A method (200) for fabricating an asymmetrical non-volatile memory cell on a substrate of first conductivity type, the method comprises
providing a control region adjacent to a floating region on the substrate (202);
performing an implantation process in the control region (204) to form an implant region, having second conductivity type, across the control region, wherein the second conductivity type is different from the first conductivity type;
forming a polycrystalline silicon control gate (206) disposed entirely over the implant region of the control region;
forming a polycrystalline silicon floating gate (206) disposed entirely over a channel region and at least partially over a source implant region and a drain implant region of the floating region; and
performing an implantation process in the floating region to form a first voltage state of the drain implant region, having second conductivity type and a second voltage state of the source implant region, having second conductivity type, the drain implant region and the source implant region separated by the channel region and the first voltage state is different from the second voltage state.

10. A method for fabricating an asymmetrical non-volatile memory cell according to claim 9, wherein performing the implantation process in the control region (204) to form the implant region, having second conductivity type, across the control region further comprises performing a Buried N+ implantation process.

11. A method for fabricating an asymmetrical non-volatile memory cell according to claim 9, wherein performing the implantation process in the floating region to form the first voltage state of the drain implant region, having second conductivity type and the second voltage state of the source implant region, having second conductivity type, further comprises
applying a mask over the source implant region (208);
performing an implantation process to form a medium voltage between 3.3 Volts to 6.6 Volts, more preferably 6 Volts, lightly doped diffusion region of the drain implant region (210); and
performing an implantation process to form a low voltage between 1.35 Volts to 1.65 Volts, more preferably 1.5 Volts, lightly doped diffusion region of the source implant region (212).

12. A method for fabricating an asymmetrical non-volatile memory cell according to claim 9, wherein performing the implantation process in the floating region to form the first voltage state of the drain implant region, having second conductivity type and the second voltage state of the source implant region, having second conductivity type, further comprises
applying a mask over the source implant region (208); and
performing an implantation process to form a medium voltage between 3.3 Volts to 6.6 Volts, more preferably 6 Volts, lightly doped diffusion region of the drain implant region (210).

13. A method for fabricating an asymmetrical non-volatile memory cell according to claim 9, wherein forming the polycrystalline silicon control gate and the polycrystalline silicon floating gate (206) further comprises forming the polycrystalline silicon control gate and the polycrystalline silicon floating gate with substantially equivalent gate oxide thickness.

14. A method for fabricating an asymmetrical non-volatile memory cell according to claim 9, the method further comprises forming nitride spacers (214) over the polycrystalline silicon control gate and the polycrystalline silicon floating gate.

15. A method for fabricating an asymmetrical non-volatile memory cell according to claim 9, the method further comprises isolating the control region (106) from the floating region (104) using at least one trench (122).
